(19) United States
(12) Patent Application Publication
(10) Pub. No.: US 2012/0211716 A1
(43) Pub. Date: Aug. 23, 2012

(54) Oxygen ion implanted conductive metal oxide re-writeable non-volatile memory device

(75) Inventor: Rene Meyer, Mountain View, CA (US)

(73) Assignee: UNITY SEMICONDUCTOR CORPORATION, Sunnyvale, CA (US)

(21) Appl. No.: 12/932,384

(22) Filed: Feb. 23, 2011

(51) Int. Cl. H01L 45/00

(52) U.S. Cl. 257/2; 257/E45.002

(57) ABSTRACT

A memory device having at least one layer of oxygen ion implanted conductive metal oxide (CMO) is disclosed. The oxygen ion implanted CMO includes mobile oxygen ions. The oxygen ion implanted CMO can be annealed and the annealing can optionally occur in an ambient. An insulating metal oxide (IMO) layer is in direct contact with the oxygenated CMO layer and is electrically in series with the oxygenated CMO layer. A two-terminal memory element is formed by the IMO and CMO layers. The oxygenated CMO layer includes additional mobile oxygen ions operative to improve data retention and cycling of the two-terminal memory element. As deposited, the CMO layer can lose mobile oxygen ions during the fabrication process and the ion implantation serves to increase a quantity of mobile oxygen ions in the CMO layer.

### FIELD OF THE INVENTION

The present invention relates generally to conductive metal oxide memory devices. More specifically, the present invention relates to memory devices including a layer of oxygenated conductive metal oxide formed by oxygen ion implantation.

### BACKGROUND OF THE INVENTION

Resistive random access memory (RRAM) devices can be re-writeable non-volatile memory devices that incorporate two-terminal memory elements. In some RRAM technologies, the memory element is based on a conductive metal oxide (CMO) material that includes mobile oxygen ions that can be transported into and out of the CMO in response to an electric field generated in the CMO (e.g., generated by a write voltage during write operations to the memory element). A portion of the mobile oxygen ions can be transported under the electric field into and out of an adjacent layer that is in contact with the CMO, such as a layer of insulating metal oxide (IMO) that is permeable to the mobile oxygen ions during write operations where the magnitude of the electric field is large enough to cause the portion of mobile oxygen ions to be transported. Transporting the portion of mobile oxygen ions into the IMO under a first direction of the electric field can be operative to write a first resistive value (e.g., to program the memory element). On the other hand, transporting the portion of mobile oxygen ions out of the IMO under a second direction of the electric field can be operative to write a second resistive value (e.g., to erase the memory element). In some applications, the memory element is configured to store one-bit of data (e.g., a single level cell—SLC) and in other applications; the memory element is configured to store more than one-bit of data (e.g., a multi level cell—MLC). In some SLC applications, the data values stored in the memory element can be indicative of a logic “0” (e.g., programmed state) or a logic “1” (e.g., an erased state). For some MLC applications, the data values stored in the memory element can be indicative of a logic “00” (e.g., a soft programmed state), a logic “01” (e.g., a hard programmed state), a logic “10” (e.g., a soft erased state), or a logic “11” (e.g., a hard erased state). In either case, data retention is a measure of how long data stored in the memory element retains its resistive state over time. Ideally, there would be no degradation or alteration of the resistive state stored in the memory element. Cycling is a measure of the ability of the memory element to be repeatedly written to (e.g., number of write cycles) and/or read from without degrading the resistive state stored in the memory element. In that typically, a magnitude of the write voltages applied across the two-terminals of the memory element are higher than a magnitude of read voltages applied across the two-terminals of the memory element, write voltages can have a greater impact on data retention and cycling than read voltages.

During fabrication of the memory device, the mobile oxygen ions in the CMO can be displaced from the CMO by some of the processing steps. After processing, there can be additional loss of mobile oxygen ions from the CMO. Either one of those loss mechanisms can result in reduced data retention and/or cycling in the memory element. Ideally, the CMO contains enough mobile oxygen ions for consistent and reliable performance and operation of the memory device.

There are continuing efforts to improve performance and reliability of non-volatile memory devices.

### BRIEF DESCRIPTION OF THE DRAWINGS

The invention and its various embodiments are more fully appreciated in connection with the following detailed description taken in conjunction with the exampled depicted in the accompanying drawings, in which:

FIG. 1 is a cross-sectional view depicting a memory element including an oxygenated CMO layer in contact with a IMO layer;

FIG. 1A is a cross-sectional view depicting mobile oxygen ion transport from CMO to IMO during application of a first write voltage;

FIG. 1B is a cross-sectional view depicting mobile oxygen ion positions after the first write voltage is removed;

FIG. 1C is a cross-sectional view depicting mobile oxygen ion transport from IMO to CMO during application of a second write voltage;

FIG. 1D is a cross-sectional view depicting mobile oxygen ion positions after the second write voltage is removed;

FIG. 1E is a cross-sectional view depicting mobile oxygen ion positions during a read operation when data is stored in a programmed state;

FIG. 1F is a cross-sectional view depicting mobile oxygen ion positions during a read operation when data is stored in an erased state;

FIG. 1G is a cross-sectional view depicting a memory element including an oxygenated CMO layer in contact with a IMO layer and having first and second terminals;

FIG. 2A is a profile view depicting a section of a two-terminal cross-point memory array that include a discrete two-terminal memory element positioned between a cross-point of conductive array lines;

FIG. 2B is a schematic view depicting a discrete two-terminal memory element in a two-terminal cross-point memory array;

FIG. 2C is a profile view depicting a two-terminal cross-point memory array that include a plurality of discrete two-terminal memory elements;

FIG. 2D is a profile view depicting a multi-layer vertically stacked two-terminal cross-point memory array that include a plurality of discrete two-terminal memory elements;

FIG. 3 is a cross-sectional view depicting a first example of ion implantation of oxygen ions into a CMO layer to oxygenate the CMO layer and optional annealing in an oxygen ambient;

FIG. 3A is a cross-sectional view depicting a second example of ion implantation of oxygen ions into a CMO layer to oxygenate the CMO layer and optional annealing in an oxygen ambient;

FIG. 3B is a cross-sectional view depicting a third example of ion implantation of oxygen ions into a CMO layer to oxygenate the CMO layer and optional annealing in an oxygen ambient;

FIG. 3C is a cross-sectional view depicting a post ion implantation view of the CMO of FIG. 3B and an optional ion implantation process;

FIG. 4 is a cross-sectional view depicting an example of ion implantation of oxygen ions into multiple layers of CMO to oxygenate one or more of the multiple layers and optional annealing in an oxygen ambient;

FIG. 5 is a cross-sectional view depicting a first example of an encapsulation material for containing mobile oxygen ions in an oxygenated CMO layer;

FIG. 6A is a top plan view depicting a second example of an encapsulation material for containing mobile oxygen ions in an oxygenated CMO layer;

FIG. 6B is a cross-sectional view depicting a third example of an encapsulation material for containing mobile oxygen ions in an oxygenated CMO layer;

FIG. 7A is a schematic view depicting a plurality of discrete two-terminal memory elements positioned in a two-terminal cross-point memory array and a data operation on a selected memory element;

FIG. 7B is a profile view depicting a plurality of discrete two-terminal memory elements positioned in a two-terminal cross-point memory array and a data operation on a selected memory element and placement of half-selected memory elements in the array;

FIG. 8A is a cross-sectional view of a unitary die for an integrated circuit including a FEOL circuitry portion and an integrally fabricated BEOL vertically stacked memory portion;

FIG. 8B is a cross-sectional view of a unitary die for an integrated circuit including a FEOL circuitry portion and an integrally fabricated BEOL vertically stacked memory portion including multiple layers or planes of BEOL memory with electrically isolated conductive array lines in each memory plane;

FIG. 8C is a cross-sectional view of a unitary die for an integrated circuit including a FEOL circuitry portion and an integrally fabricated BEOL vertically stacked memory portion including multiple layers or planes of BEOL memory with memory planes having shared conductive array lines;

FIG. 8D is a profile view of a unitary die for an integrated circuit including a FEOL circuitry portion and an integrally fabricated BEOL vertically stacked memory portion including a single layer of BEOL memory or multiple layers or planes of BEOL memory; and

FIG. 9 is a top plan view depicting a fabrication flow for a semiconductor wafer first processed to form FEOL circuitry and subsequently processed to form one or more layers of BEOL memory directly on top of the FEOL circuitry to form a unitary die that can be subsequently packaged.

Although the above-described drawings depict various examples of the invention, the invention is not limited by the depicted examples. It is to be understood that, in the drawings, like reference numerals designate like structural elements. Also, it is understood that the drawings are not necessarily to scale.

### DETAILED DESCRIPTION

Various embodiments or examples of the invention may be implemented in numerous ways, including as a system, a process, an apparatus, or a series of program instructions on a computer readable medium such as a computer readable storage medium or a computer network where the program instructions are sent over optical, electronic, or wireless communication links. In general, operations of disclosed processes may be performed in an arbitrary order, unless otherwise provided in the claims.

A detailed description of one or more examples is provided below along with accompanying figures. The detailed description is provided in connection with such examples, but is not limited to any particular example. The scope is limited only by the claims, and numerous alternatives, modifications, and equivalents are encompassed. Numerous specific details are set forth in the following description in order to provide a thorough understanding. These details are provided as examples and the described techniques may be practiced according to the claims without some or all of the accompanying details. For clarity, technical material that is known in the technical fields related to the examples has not been described in detail to avoid unnecessarily obscuring the description.

U.S. patent application Ser. No. 11/095,026, filed Mar. 30, 2005, published as U.S. Pub. No. 2006/0171200, and entitled “Memory Using Mixed Valence Conductive Oxides,” is hereby incorporated by reference in its entirety for all purposes and describes non-volatile third dimensional memory elements that may be arranged in a two-terminal cross-point memory array. New non-volatile memory structures are possible with the capability of this third dimensional memory array. In at least some embodiments, a two-terminal memory element or memory cell can be configured to change conductivity when exposed to an appropriate voltage drop across its two-terminals. The memory element can include an electrolytic tunnel barrier in contact with and electrically in series with a mixed valence conductive oxide that includes mobile oxygen ions in some embodiments, as well as multiple layers of mixed valence conductive oxide structures in other embodiments. The electrolytic tunnel barrier comprises an electronically insulating material that is thin enough to promote electron tunneling during data operations on the memory element (e.g., read and write operations) while also promoting a high electric field during write operations operable to cause the mobile oxygen ions to be transported into or out of the electrolytic tunnel barrier depending on the direction of the electric field within the memory element. The direction of the electric field is determined by the polarity of the write voltage. Therefore, the electrolytic tunnel barrier is permeable to the mobile oxygen ions and is operative as an electrolyte to the mobile oxygen ions. The mobile oxygen ions are transported between the electrolytic tunnel barrier and the mixed valence conductive oxide in response to an electric field generated by the application of the write voltage across the electrolytic tunnel barrier and the mixed valence conductive oxide. Examples of conductive metal oxides suitable for use as the mixed valence conductive oxide includes but is not limited to perovskites and binary oxides (e.g., a conductive binary oxide). Application of a write voltage across the memory element is operative to create a voltage drop across the electrolytic tunnel barrier that generates a higher electric field within the electrolytic tunnel barrier that is operative to transport a portion of the mobile oxygen ions in the mixed valence conductive oxide into the electrolytic tunnel barrier for a first polarity of the write voltage and to transport the portion of portion of the mobile oxygen ions in the electrolytic tunnel barrier back into the mixed valence conductive oxide for a second polarity of the write voltage, the second polarity is opposite the first polarity.

In some embodiments, an electrolytic tunnel barrier and one or more mixed valence conductive oxide structures do not need to operate in a silicon substrate (e.g., a silicon die or silicon wafer), and, therefore, can be fabricated back-end-of-the-line (BEOL) directly above circuitry fabricated front-end-of-the-line (FEOL) on the semiconductor substrate and being used for other purposes. Further, a two-terminal memory element can be configured in a cross-point such that one terminal of the memory element is electrically coupled with an X-direction line (or an “X-line”) and the other terminal of the memory element is electrically coupled with a Y-direction line (or a “Y-line”). A discrete two-terminal memory element is one in which the two terminals of the memory element are directly electrically coupled with the conductive array lines (e.g., X-line and Y-line or a Word-line and Bit-line) at its respective cross-point without any intervening structure such as a selection device, also known as a non-ohmic device (NOD). Therefore, a discrete two-terminal memory element is one that is directly electrically in series with its respective conductive array lines. Examples of a selection devices/NOD include metal-insulator-metal (MIM) devices or one or more diodes that comprise an intervening structure that is electrically in series with the memory element and with the conductive array lines. Another example includes a three-terminal memory device (e.g., a 1T-1R memory cell) including at least one transistor with a source and drain electrically in series with the memory element and the transistors gate electrically coupled with a select signal that when active allows the memory element to be selected for data operations (e.g., read or write operations).

Unless otherwise specified herein, all references to a memory element or memory cell is a reference to a discrete memory element or discrete memory cell that does not include a selection device or NOD. A third dimensional memory can include multiple memory layers that are vertically stacked upon one another, with memory elements in a memory layer that sometimes share X-direction and Y-direction lines with memory elements in adjacent memory layers. In other embodiments, the memory elements in each memory layer have electrically isolated conductive array lines and do not share conductive array lines with memory elements in adjacent memory layers. When a first write voltage, VW1, is applied across the memory element (e.g., by applying ½ VW1 to the X-direction line and ½ −VW1 to the Y-direction line), the memory element can switch to a low resistive state. When a second write voltage, VW2, is applied across the memory element (e.g., by applying ½ VW2 to the X-direction line and ½ −VW2 to the Y-direction line), the memory element can switch to a high resistive state. Memory elements using electrolytic tunnel barriers and mixed valence conductive oxides can have VW1 opposite in polarity from VW2.

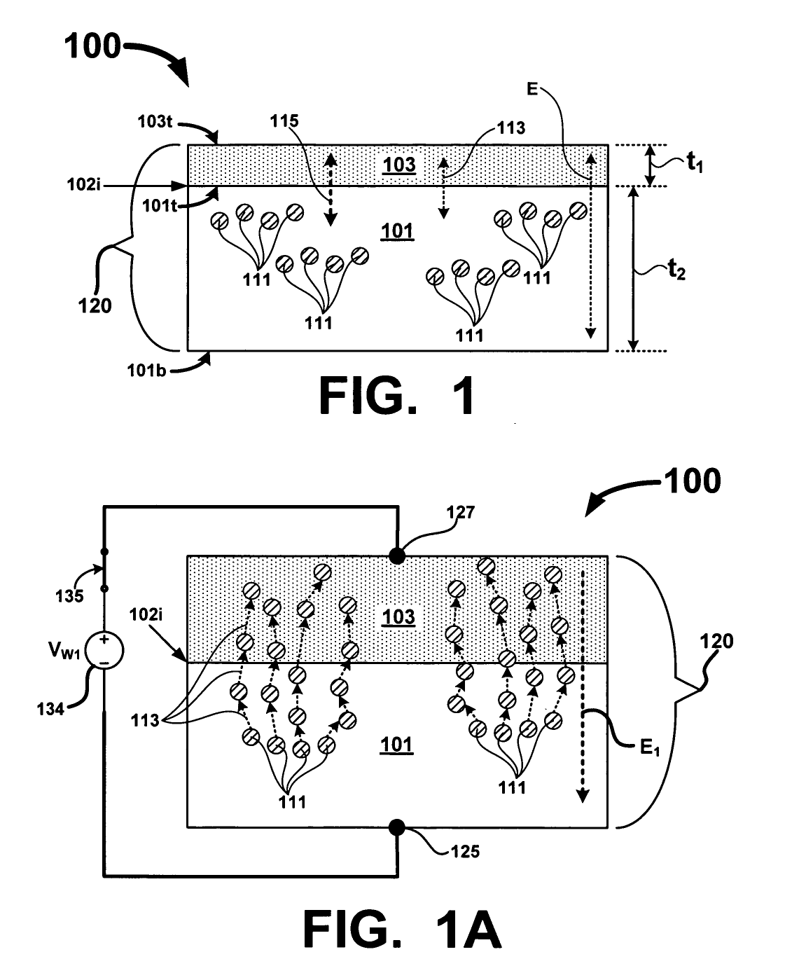

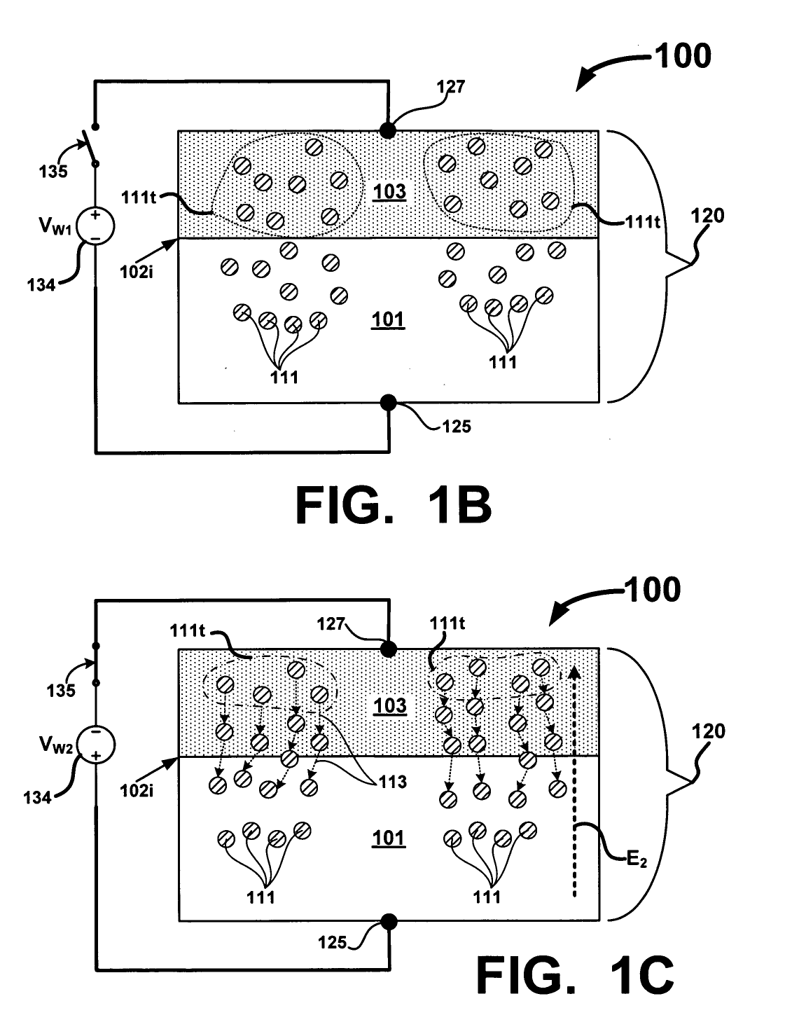

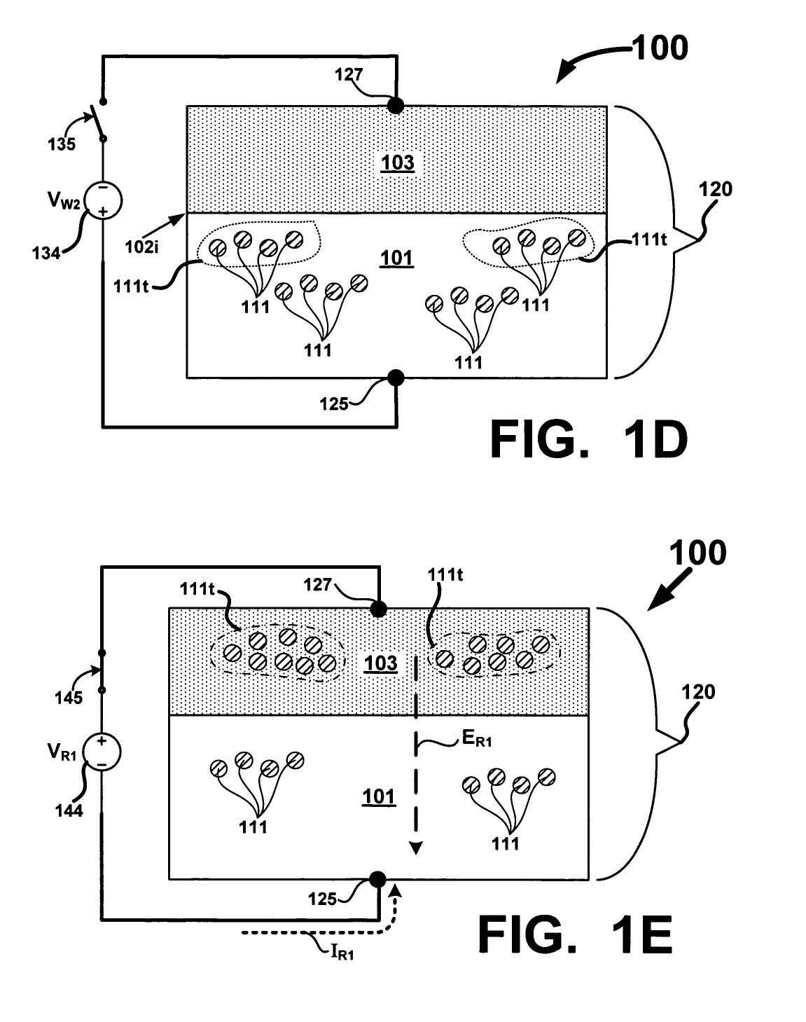

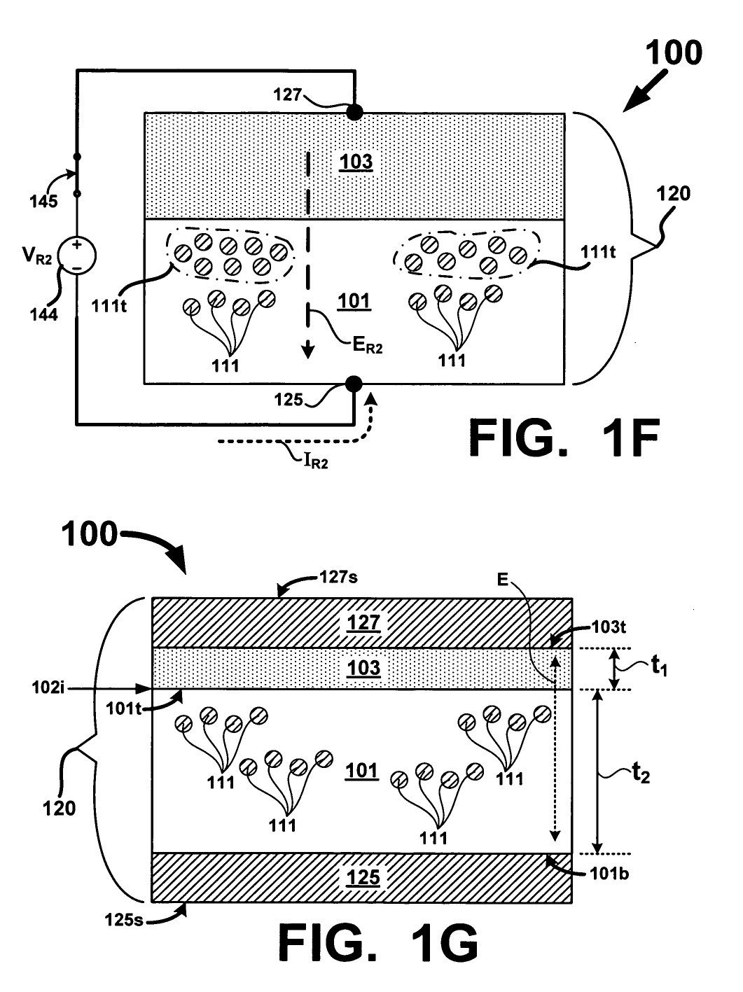

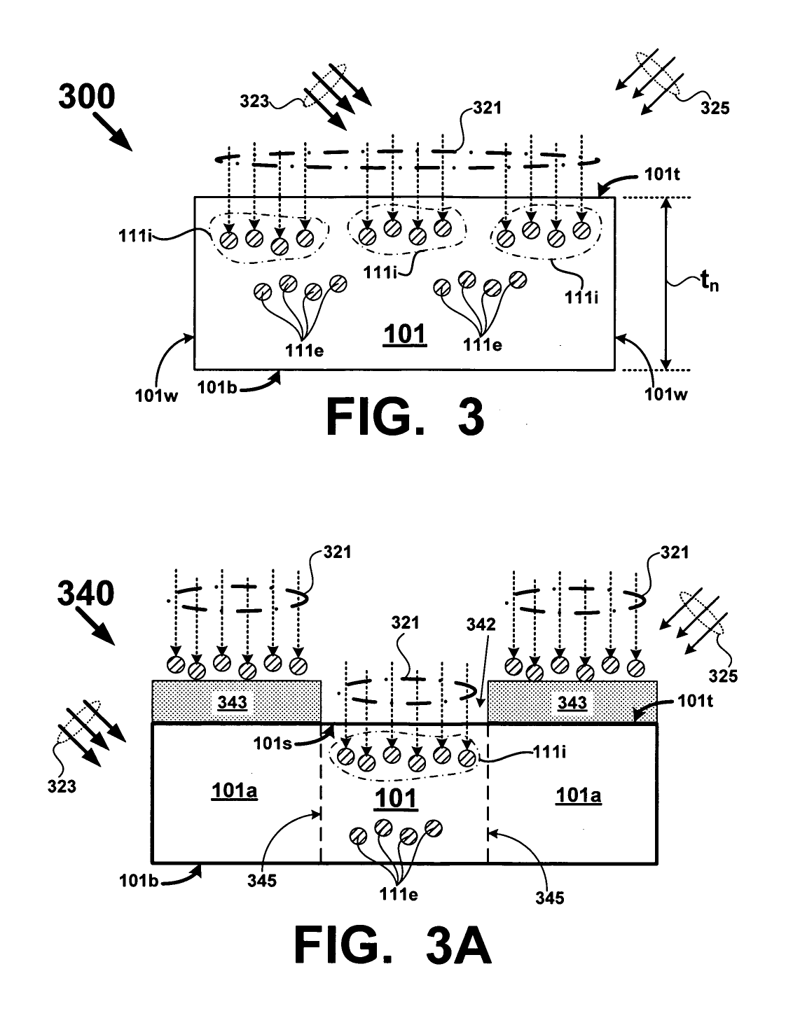

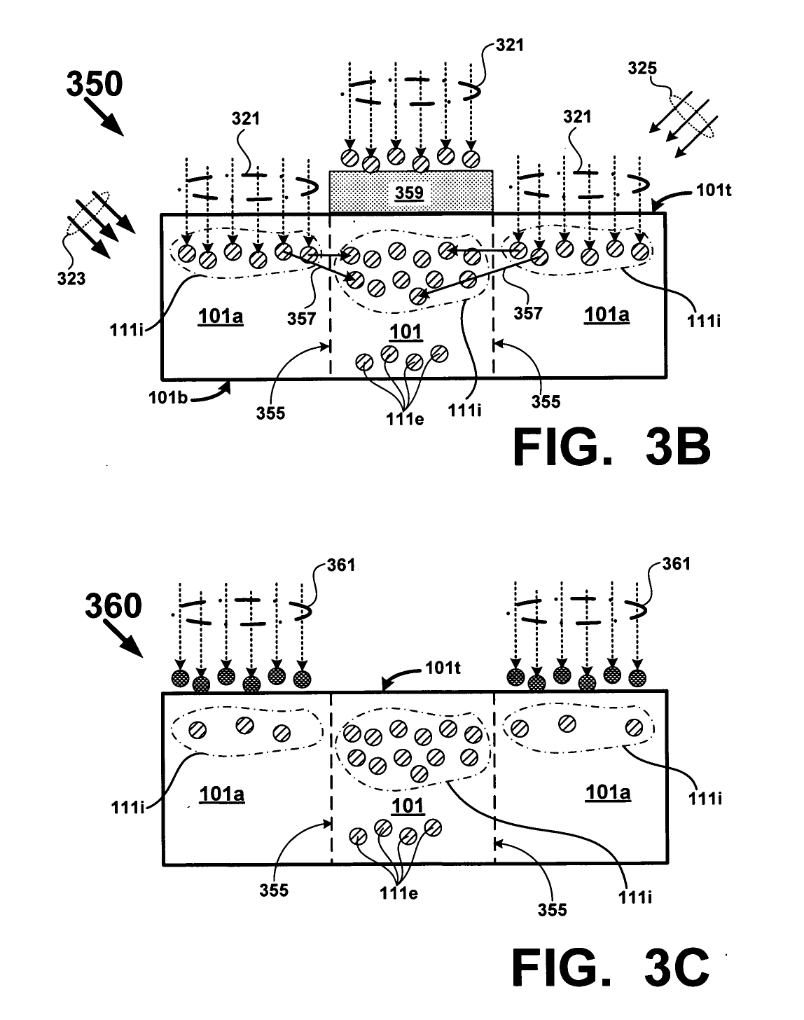

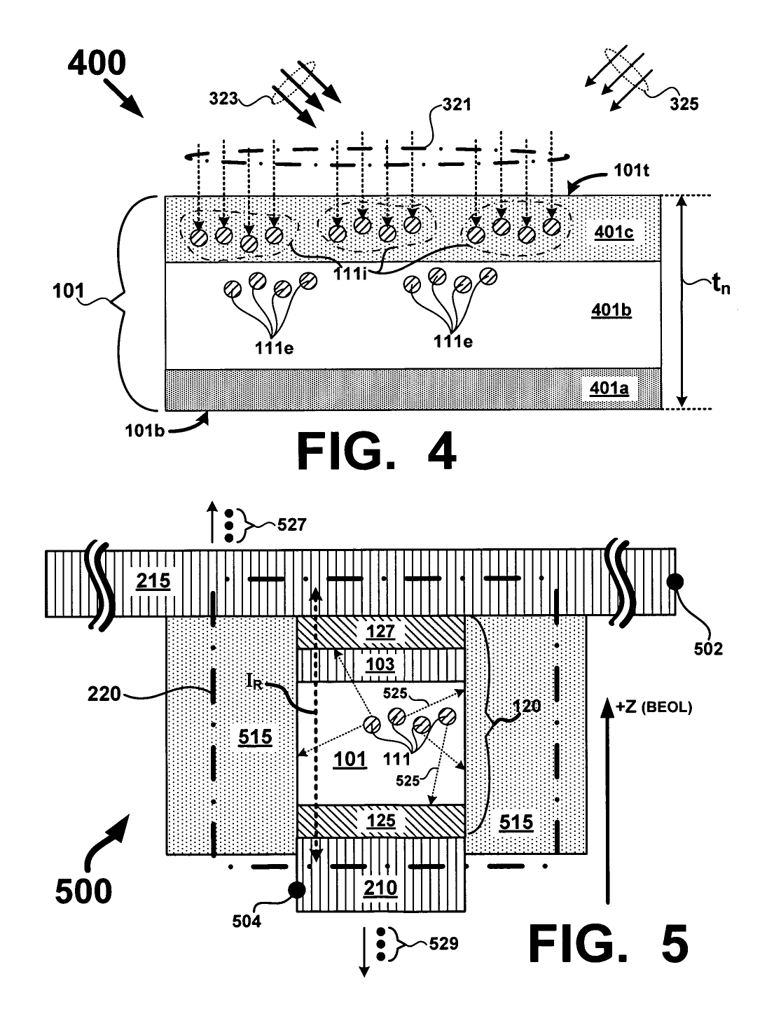

Attention is now directed to FIG. 1 where a memory device 100 includes two-terminal re-writeable non-volatile memory element 120 (memory element 120 hereinafter) including an oxygenated conductive metal oxide (CMO) layer that includes mobile oxygen ions 111 and an insulating metal oxide (IMO) layer 103 that is in direct contact with and is electrically in series with CMO layer 101. The CMO layer 101 comprises an oxygen ion implanted layer in which during fabrication of the memory device 100, ion implantation using oxygen ions has been performed on the layer 101 to oxygenate the layer 101 thereby adding additional mobile oxygen ions 111 to the number of mobile oxygen ions 111 that existed in the CMO layer 101 prior to the oxygen ion implantation process. Examples of the oxygen ion implantation process will be discussed below in regards to FIGS. 3-4. The CMO layer 101 can be an annealed layer, such as an oxygen annealed layer (e.g., annealing the CMO layer 101 at a temperature and time in an oxygen ambient). Examples of an annealing process for the CMO layer 101 will be discussed below in regards to FIGS. 3-4.

In FIG. 1, application of a write voltage across the in electrically series combination of the IMO layer 103 and CMO layer 101 generates an electric field E operative to transport 113 the mobile oxygen ions 111 between the layer 103 and 101 depending on the polarity of the write voltage. The IMO layer 103 has a first thickness t1 selected to allow electron tunneling 115 during data operations (e.g., read and write operations) to the memory element 120. Typically the first thickness t1 form IMO layer 103 is approximately 50 Angstroms or less in thickness. Actual values for t1 will be application dependent. Example ranges for the first thickness t1 include but are not limited to a range from about 5′ to about 35′. Preferably, the first thickness t1 is substantially uniform across an interface 102i with the CMO layer 101. The CMO layer 101 has a second thickness t2 that is typically greater than the first thickness t1. Actual values for t2 will be application dependent. Example ranges for the second thickness t1 include but are not limited to a range from about 40′ to about 350′. The IMO layer 101 can be the electrolytic tunnel barrier described above and the CMO layer 101 can be the mixed valence conductive oxide that includes mobile oxygen ions as described above. Here, the quantity of mobile oxygen ions in the mixed valence conductive oxide is increased by the oxygen ion implantation as will be described below. The CMO layer 101 can be a single layer or multiple layers and the multiple layers can include different types of CMO's.

FIG. 1A depicts mobile oxygen ion transport 113 when a first write voltage VW1 is applied across first 125 and second 127 terminals of the memory element 120 by voltage source 134 (e.g., a FEOL driver circuit) when switch 135 (e.g., a FEOL switch or the like) is closed. Here, a portion of the mobile oxygen ions 111 in oxygenated CMO layer 101 are transported 113 from the CMO layer 101 and into the IMO layer 103 in response to a first electric field E1 generated by application of the first write voltage VW1. Transported 113 mobile ions 111 pass through an interface 102i between the layers 101 and 103.

In FIG. 1B, the switch 135 is open thereby removing the first write voltage VW1 across the first and second terminals (125, 127). As a result, the transported mobile ions denoted as 111t, are disposed in the IMO layer 103 and remain positioned in the IMO layer 103 until a subsequent write operation generates an electric field operative to transport the mobile ions 111t back into the CMO layer 101 as will be described below. The configuration depicted in FIG. 1B changes a conductivity of the memory element 120 such that the memory element stores non-volatile data as a first resistive state (e.g., a high resistance programmed state).

Moving on to FIG. 1C, voltage source 134 applies a second write voltage VW2 across the first and second terminals (125, 127) operative to generate a second electric field E2 operative to transport 113 mobile ions 111t from the IMO layer 103 and back into the CMO layer 101 with the mobile ions 111t passing through the interface 102i. Here, the second electric field E2 is opposite in direction to the first electric field E1. The magnitudes of E1 and E2 can be the same or different and will depend on the magnitudes of their respective write voltages VW1 and VW2. Although not depicted in FIGS. 1A and 1C, electron tunneling 115 can occur during application of the write voltages VW1 and VW2.

Referring now to FIG. 1D, switch 134 is now open thereby removing the second write voltage VW2 across the first and second terminals (125, 127). As a result, the transported mobile ions denoted as 111t, are disposed in the oxygenated CMO layer 101 and remain positioned in the CMO layer 101 until a subsequent write operation generates an electric field operative to transport the mobile ions 111t back into the IMO layer 103, as depicted in FIG. 1A. The configuration depicted in FIG. 1C changes a conductivity of the memory element 120 such that the memory element stores non-volatile data as a second resistive state (e.g., a low resistance erased state).

In FIG. 1E, one example of a read operation on memory element 120 in a programmed state is depicted. Here, a voltage source 144 (e.g., a FEOL driver circuit) applies a first read voltage VR1 across the first and second terminals (125, 127) when switch 145 (e.g., a FEOL switch or the like) is closed. Even though a read electric field ER1 is generated by the application of the first read voltage VR1, the magnitude of the read electric field ER1 is insufficient to cause the aforementioned transport 113 of the mobile oxygen ions 111t, and a portion of the mobile ions 111t remain disposed in the IMO layer 103. Consequently, the programmed state of the memory element 120 is not overwritten by the first read voltage VR1 and the first read voltage VR1 generates a first read current IR1 in the memory element 120. A magnitude of the first read current IR1 can be sensed by circuitry (e.g., FEOL sense amp circuitry) to determine the value of non-volatile data stored in the memory element 120 (e.g., a logic “0” for the high resistance programmed state).

In FIG. 1F, another example of a read operation on memory element 120 in an erased state is depicted. Here, a voltage source 144 (e.g., a FEOL driver circuit) applies a second read voltage VR2 across the first and second terminals (125, 127) when switch 145 (e.g., a FEOL switch or the like) is closed. Even though a read electric field ER2 is generated by the application of the second read voltage VR2, the magnitude of the read electric field ER2 is insufficient to cause the aforementioned transport 113 of the mobile oxygen ions 111t, and a portion of the mobile ions 111t remain disposed in the CMO layer 101. Consequently, the erased state of the memory element 120 is not overwritten by the second read voltage VR2 and the second read voltage VR2 generates a second read current IR2 in the memory element 120. A magnitude of the second read current IR2 can be sensed by circuitry (e.g., FEOL sense amp circuitry) to determine the value of non-volatile data stored in the memory element 120 (e.g., a logic “1” for the low resistance erased state). The first and second read voltages (VR1, VR2) can have voltages of the same magnitude, the same polarity or can have voltages that are different and/or of different polarities. In FIGS. 1E and 1F, the magnitudes of the first and second read voltages (VR1, VR2) are less than the magnitudes of the aforementioned first and second write voltages (VW1, VW2).

Now in regards to FIG. 1G, the memory device 100 is depicted with a memory element 120 that includes first and second terminals (125, 127). First terminal 125 is directly electrically coupled with the oxygenated CMO layer 101 and in some application can be in direct contact with the oxygenated CMO layer 101. Second terminal 127 is directly electrically coupled with the IMO layer 103 and in some application can be in direct contact with the IMO layer 103. The IMO layer 103 and the oxygenated CMO layer 101 are electrically in series with each other and with the first and second terminals (125, 127).

As used herein, the word terminal can include an electrode made from an electrically conductive material such as a metal or a metal alloy, or it can include a plurality of electrically conductive thin film materials that are operative to electrically couple the memory element 120 with circuitry (e.g., FEOL circuitry) that performs data operations on the memory element 120 via electrical coupling with the first and second terminals (125, 127) or with conductive array lines the first and second terminals (125, 127) are electrically coupled with. The first and second terminals (125, 127) can include electrically conductive glue layers, adhesion layers, barrier layers, and the like, for example. Surfaces 125s and 127s of the first and second terminals (125, 127) can be in direct contact with and/or electrically coupled with conductive array lines (e.g., in a cross-point array) as will be described below.

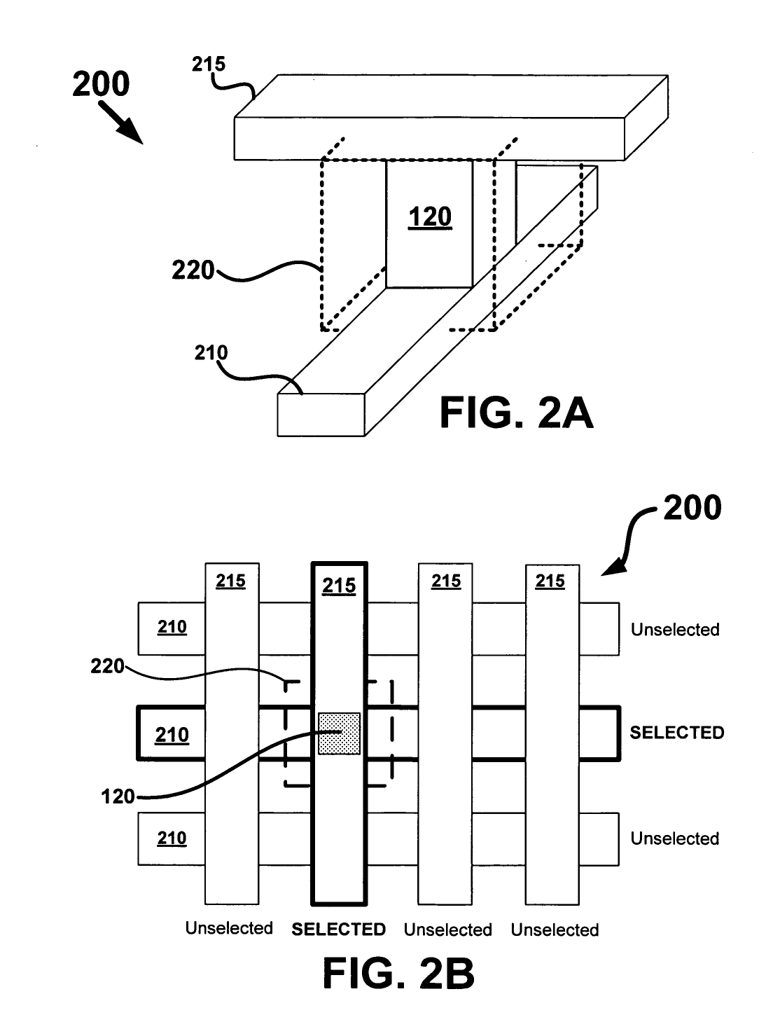

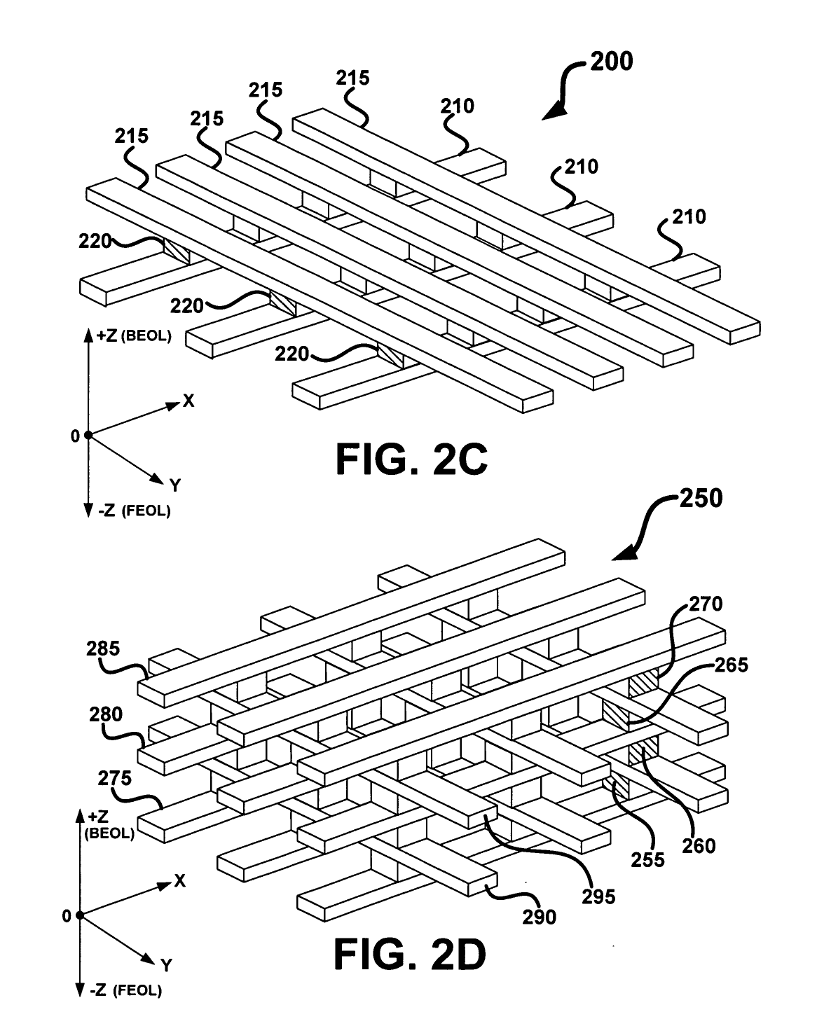

Moving on to FIG. 2A, a portion of a two-terminal cross-point array 200 is depicted with the memory element 120 positioned between and electrically in series with a first conductive array line 210 and a second conductive array line 215 that are oriented orthogonally to each other. First terminal 125 is directly electrically coupled with the first conductive array line 210 and second terminal 127 is directly electrically coupled with the second conductive array line 215. Dashed lines depict a memory cell 220 that includes the memory element 120 and can include at least a portion of the first and second conductive array lines (210, 215).

FIG. 2B depicts one example of the first and second conductive array lines (210, 215). Here, a memory cell 220 is selected for a data operation (e.g., read, write, program, erase) by applying the appropriate voltages for the data operation across selected first and second conductive array lines (210, 215 denoted in bold line) such that the memory element 120 positioned at the cross-point of the selected first and second conductive array lines (210, 215) has the intended data operation performed on it.

FIG. 2C depicts another example of the two-terminal cross-point array 200 and also depicts a plurality of the memory cells 220 and a plurality of the first and second conductive array lines (210, 215) that are fabricated BEOL along a +Z axis directly above FEOL active circuitry in a semiconductor substrate along a −Z axis (not shown).

FIG. 2D depicts yet another example of a two-terminal cross-point array 250 that also includes a plurality of the memory cells (255, 260, 265, 270, 274) and a plurality of the first and second conductive array lines (275, 280, 285, 290, 295) that are fabricated BEOL along a +Z axis directly above FEOL active circuitry in a semiconductor substrate along a −Z axis (not shown); however, in the configuration depicted, the two-terminal cross-point array 250 includes a plurality of vertically stacked memory planes or layers with memory cells in each layer that share conductive array lines with memory cells in adjacent layers.

Forming an Oxygenated CMO Layer Using Oxygen Ion Implantation

Attention is now directed to FIG. 3 where a first example 300 of oxygen ion implantation of CMO layer 101 is depicted. Depending on the materials selected for the memory element 120 and the properties of those materials, there can be one or more layers of thin film material (not shown) in contact with the CMO layer 101 prior to the ion implantation process (e.g., a layer of material disposed on surface 101t of the CMO layer 101). The ion implantation can occur with the presence of those materials so long as the implantation does not result in damage to those layers and so long as the implanted ions can pass thorough those layers and into the CMO layer 101 as intended to produce an efficacious oxygenated CMO layer 101. For example, IMO layer 103 can already be in contact with the CMO layer 101 prior to the implantation.

In FIG. 3, the CMO layer 101 includes mobile oxygen ions 111e present in the CMO layer 101 prior to ion implantation. A quantity of the mobile oxygen ions 111e can be less than when the CMO layer 101 was deposited or otherwise formed in the memory element 120. For example, the CMO layer may have been deposited using physical deposition processes that are well understood in the microelectronics including but not limited to sputtering, co-sputtering, ALD, PVD, CVD, MOCVD, PECVD, and the like. During the deposition process or subsequent to the deposition process an initial quantity of mobile oxygen ions in the CMO layer 101 may have been displaced or otherwise removed (e.g., dissipated or out gassed) from the CMO layer 101, reducing the initial quantity and leaving the quantity of the mobile oxygen ions 111e depicted in FIG. 3. For example, some of the initial quantity of mobile oxygen ions may have escaped through surfaces 101t, 101b, and 101w.

At some stage in the processing of the memory element 120, an ion implantation of oxygen ions 321 is conducted to implant an additional quantity of mobile oxygen ions 111i into the CMO layer 101 to form an oxygenated CMO layer 101. Here, ion implantation of oxygen ions 321 occurs through the surface 101t and the additional quantity of mobile oxygen ions 111i enter into the bulk of the CMO layer 101. Ion penetration depth, ion distribution, and ion concentration as a function of depth into the CMO layer 101 will be application dependent and can be controlled by factors such as implantation dose, implantation energy, and orientation of the CMO layer 101 relative to the ion beam, just to name a few.

Subsequent to the ion implantation 321 or in parallel with the ion implantation 321, the CMO layer 101 can be annealed 323 and the anneal 323 can occur in an ambient 325 such as an oxygen ambient, for example. Here, the CMO layer 101 can be positioned in one of a plurality of die on a BEOL portion of an integrated circuitry (IC) where a silicon wafer comprises a work piece that is mounted to a chuck, platen, or the like. Direct or indirect heating of the work piece can be used to perform the annealing 323 and the annealing 323 can occur in a chamber into which the ambient 325 is introduced. The ambient 325 (e.g., an oxygen—O² or ozone—O³ ambient) can be used to introduce additional oxygen into the CMO layer 101, to prevent additional oxygen from escaping the CMO layer 101, or both.

In FIG. 3A, another example of ion implantation to oxygenate the CMO layer 101 includes a patterned mask layer 343 in contact with a portion of surface 101t so that a remaining portion of surface 101t is not covered by the mask layer 343 and is exposed 101s by an aperture 342 in the mask layer 343. Ion implantation of the exposed portion of surface 101t occurs through the aperture 342 and the implanted ions penetrate into the CMO layer 101 to oxygenate the CMO layer 101. As described above, the oxygenate CMO layer 101 can also be annealed 323 and the annealing 323 can occur in an oxygen ambient 325. The patterned mask layer 343 can be a material such as photoresist or some other thin film material suitable as an implantation mask. Here, the implanted ions 321 do not penetrate the mask layer 343 such that adjacent regions 101a of the CMO layer 101 are not implanted with the oxygen ions. In FIG. 3A, dashed lines 345 approximately demarcate the portion of the CMO layer 101 that comprises the active area of the memory element 120. After the ion implantation 321, the oxygenated CMO layer now includes the mobile oxygen ions 111e present in the CMO layer 101 prior to ion implantation and the implanted ions 111i thereby increasing the quantity of mobile oxygen ions in the active region of the memory element 120.

Moving on to FIG. 3B, yet another example of ion implantation to oxygenate the CMO layer 101 includes a patterned mask layer 359 in contact with a portion of surface 101t and approximately aligned with dashed lines 355 which approximately demarcate the portion of the CMO layer 101 that comprises the active area of the memory element 120. Prior to the ion implantation 321, mobile oxygen ions 111e are present in the CMO layer 101. During ion implantation 321, oxygen ions 111i are implanted into the adjacent regions 101a. Subsequently, the anneal 323 and/or oxygen ambient 325 are operative to drive 357 a portion of the oxygen ions 111i from the adjacent regions 101a into the active region of the CMO layer 101 thereby increasing the quantity of quantity of mobile oxygen ions in the active region of the memory element 120 as depicted in FIG. 3C.

In FIG. 3C, for purposes of illustration, the mask layer 359 has been removed (e.g., by etching or stripping). FIG. 3 depicts an optional implantation step can be performed to transform the adjacent CMO regions 101a into a CMO that is less electrically conductive or is electrically insulating so that the active and oxygenated region of the CMO layer 101 that now includes the increased quantity of mobile oxygen ions (111e and 111i) is electrically isolated from the adjacent regions. An ion implantation 361 with one or more species of ions, other than oxygen ions can be used to reduce the conductivity of the adjacent CMO regions 101a or to convert the adjacent CMO regions 101a into an essentially insulating metal oxide (IMO) that is different in properties than the IMO layer 103. The mask layer 359 (not shown) or some other masking structure can be used to shield the active and oxygenated region of the CMO layer 101 from the ion implantation 361. In FIG. 3C, unmasked portions of the CMO layer 101a can be ion implanted 361 with a species of ion operative to reduce the conductivity of the adjacent portions 101a. Elements including but not limited to helium (He), neon (Ne), xenon (Xe), krypton (Kr), and argon (Ar) can be used as the species of implanted ion. Preferably, the adjacent portions 101a are implanted with argon (Ar) ions. In some embodiments, the adjacent portions comprise an amorphous CMO structure and the active oxygenated CMO layer 101 comprises a crystalline CMO structure (e.g., a polycrystalline structure). Issued U.S. Pat. No. 7,888,711, application Ser. No. 12/803,214, and titled “Continuous Plane Of Thin-Film Materials For A Two-Terminal Cross-Point Memory” describes various ion implantation and fabrication techniques that can be used to accomplish forming continuous layers CMO's that include electrically insulating or less conductive inactive amorphous CMO regions that are adjacent to active and electrically conductive crystalline CMO regions for a memory element and is hereby incorporated by reference for all purposes.

Turning now to FIG. 4, the ion implantation 321 described above can be applied to a multi-layer CMO configuration 400 that includes at least two layers of CMO in contact with one another (three are shown). Here, thickness tn is the sum of the individual thicknesses of CMO layers 401a, 401b, and 401c. The actual thicknesses for the CMO layers 401a, 401b, and 401c will be application dependent as will be the value of tn. Example ranges for the second thickness tn include but are not limited to a range from about 40′ to about 350′. Two or more of the CMO layers 401a, 401b, and 401c can have substantially matching crystalline orientations. For example, layer 401a can be a very thin layer of CMO fabricated to have a preferred crystalline orientation and then the layer 401b can be deposited on the layer 401a and fabricated to have crystalline orientation that substantially matches that of the layer 401a. The multiple layers of CMO need not be made from the same CMO material. Further, the thicknesses of the multiple layers of CMO need not be the same.

In FIG. 4, the ion implantation 321, the annealing 323, and the ambient 325 processing steps can be implemented to oxygenate one or more of the multiple layers of CMO 401a, 401b, and 401c. For example, if layer 401b is the active CMO layer and layers 401a and 401c are seed and cap layers, respectively, then the ion implantation 321 can be tailored (e.g., using implantation energy and dose) to implant the ions 111i into the layer 401b. Typically, seed and cap layers 401a and 401c are much thinner than the active layer 401b and so the implanted ions 111i can easily penetrate all the way through the layer 401c and into the layer 401b. In some applications, some or all of the multiple CMO layers can be implanted 321 with the ions 111i.

FIG. 5 depicts one example of an encapsulation material used to contain 525 the mobile ions 111 (i.e., 111e and 1111) in the active region of the CMO layer 101 post implantation 321. Here, the memory element 120 is positioned between the cross-point of conductive array lines (210, 215) with the first and second terminals (125, 127) electrically coupled with the array lines (210, 215). An encapsulation material 515 surrounds and is in contact with the memory element 120 and is made from a material configured to contain 525 the mobile ions 111 (i.e., 111e and 1111) in the active region of the CMO layer 101 while the memory device 100 undergoes additional fabrication steps and/or when the finished memory device 100 is fully operational (e.g., during data operations to the memory element 120). Although only a single layer of the cross-point array is depicted, encapsulation configuration 500 can be applied to multiple layers of cross-point memory as depicted by 527 and 529.

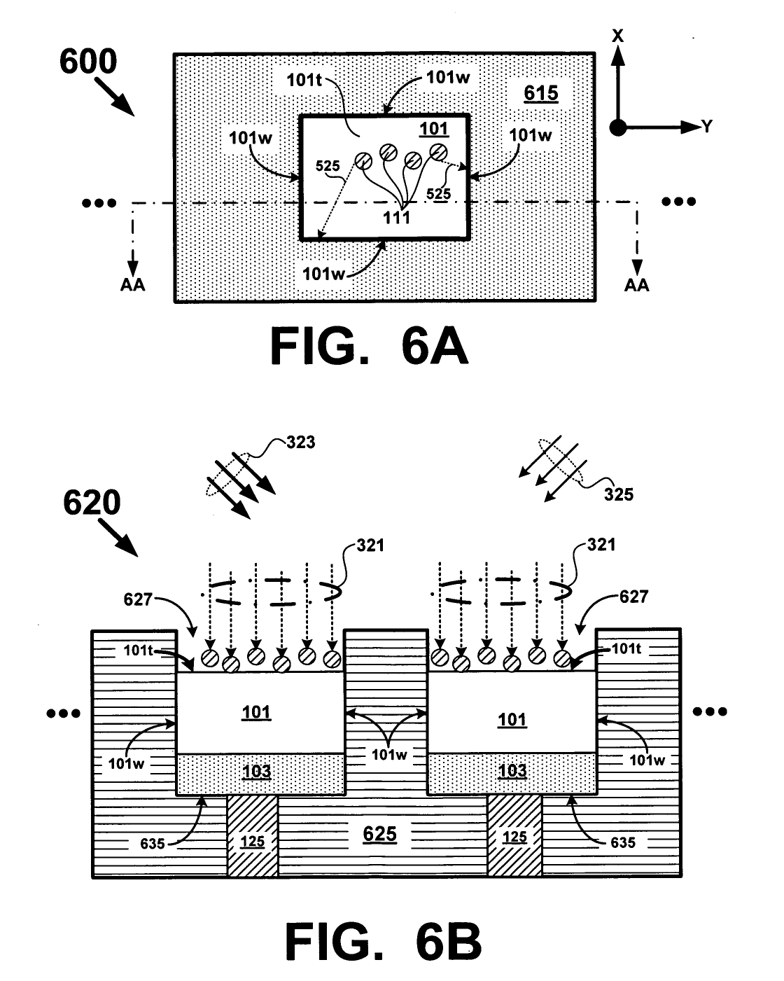

FIG. 6A depicts another example of an encapsulation configuration 600 where looking down on a surface 101t of the oxygenated CMO layer 101 an encapsulation material 615 surrounds and is in contact with the oxygenated CMO layer 101 at least along sidewall portions 101w. Encapsulation material 615 is configured to contain 525 the mobile ions 111 (i.e., 111e and 111i) in the active region of the CMO layer 101 as described above.

In FIG. 6B, a cross-sectional view along a dashed line AA of FIG. 6A depicts one example of a structure 620 in which a material 625 includes first terminals 125 previously formed therein and includes apertures 627 formed in the material 625 where subsequent fabrication processes deposit the IMO layer 103 in contact with first terminals 125 followed by a subsequent deposition of the CMO layer 101. Next, ion implantation 321 is performed to oxygenate the CMO layer 101 as described above, followed by the annealing 323 in ambient 325. The apertures 627 can be trenches, damascenes, or the like. Here, material 625 is operative as the encapsulation material as described above. Although the material 625 can contain the ions 111 along surfaces 635 and sidewall surfaces 101w, other layers of the memory element 120 (not shown) can also serve as an encapsulation material; therefore, the memory device 100 can include more than one encapsulation material and/or structure.

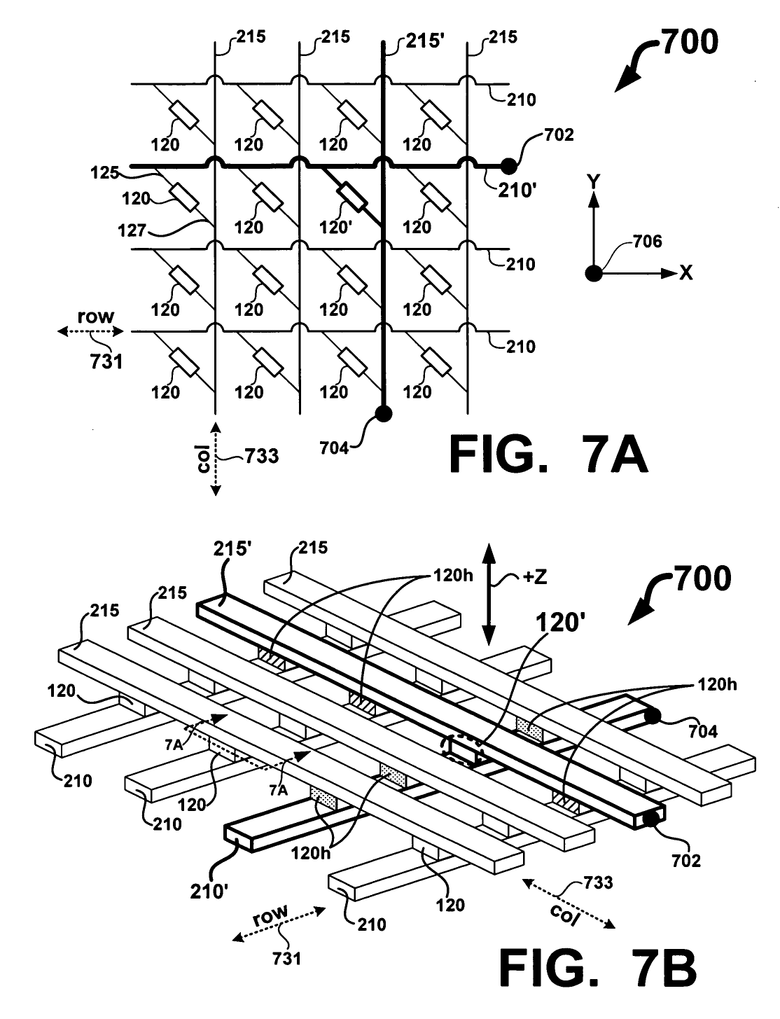

FIGS. 7A and 7B are schematic and profile views, respectively, of a two-terminal cross-point array that includes the memory element 120. In FIG. 7A, each memory element 120 is depicted as a resistive memory device having a non-linear I-V characteristic and positioned with the first terminals 125 of each memory element 120 electrically coupled with first conductive array lines 210 aligned in a row direction 731 (e.g., a word line) and the second terminals 127 of each memory element 120 electrically coupled with second conductive array lines 215 aligned in a column direction 733 (e.g., a bit line). A selected memory element 120′ is selected for a data operation by applying a read or write voltage across nodes 702 and 704 such that word line 210′ and bit line 215′ are selected conductive array lines. In FIG. 7B, selected word and bit lines 210′ and 215′ result in memory elements with terminals electrically coupled with the selected word and bit lines 210′ and 215′ being half-selected memory element 120h.

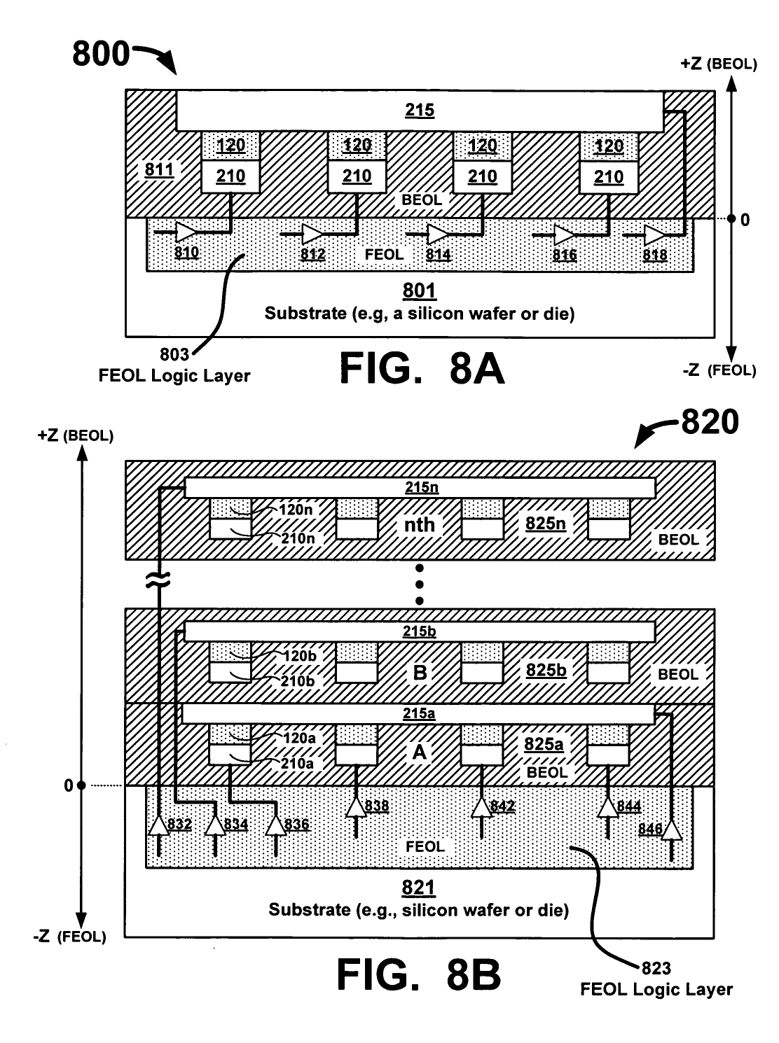

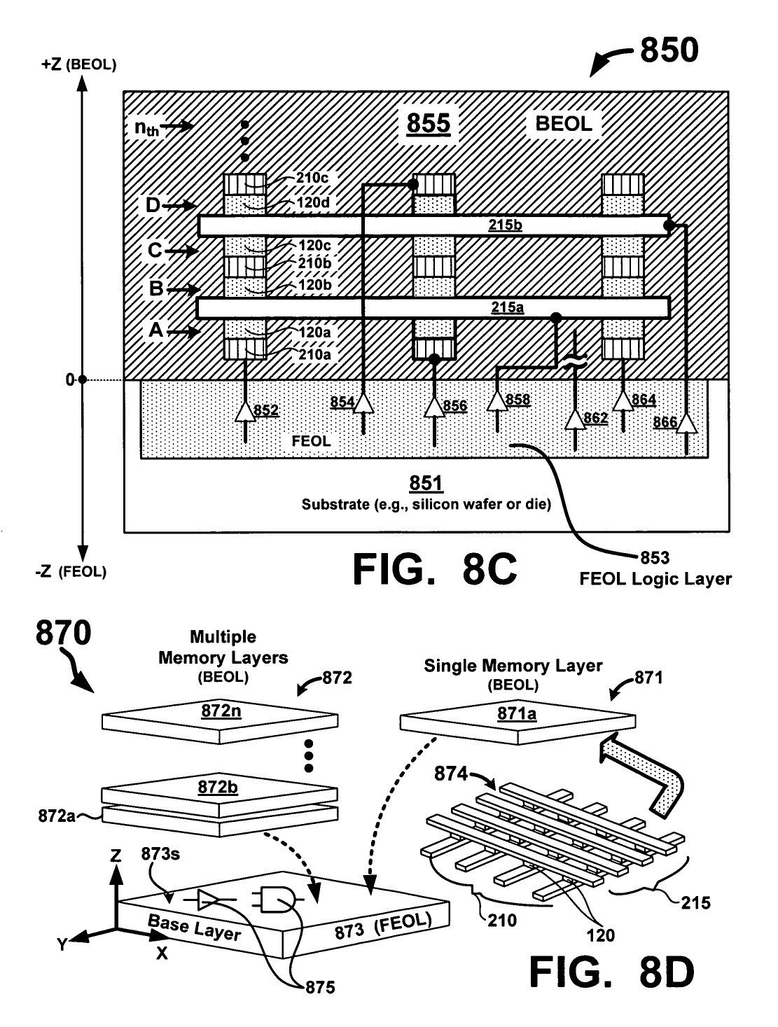

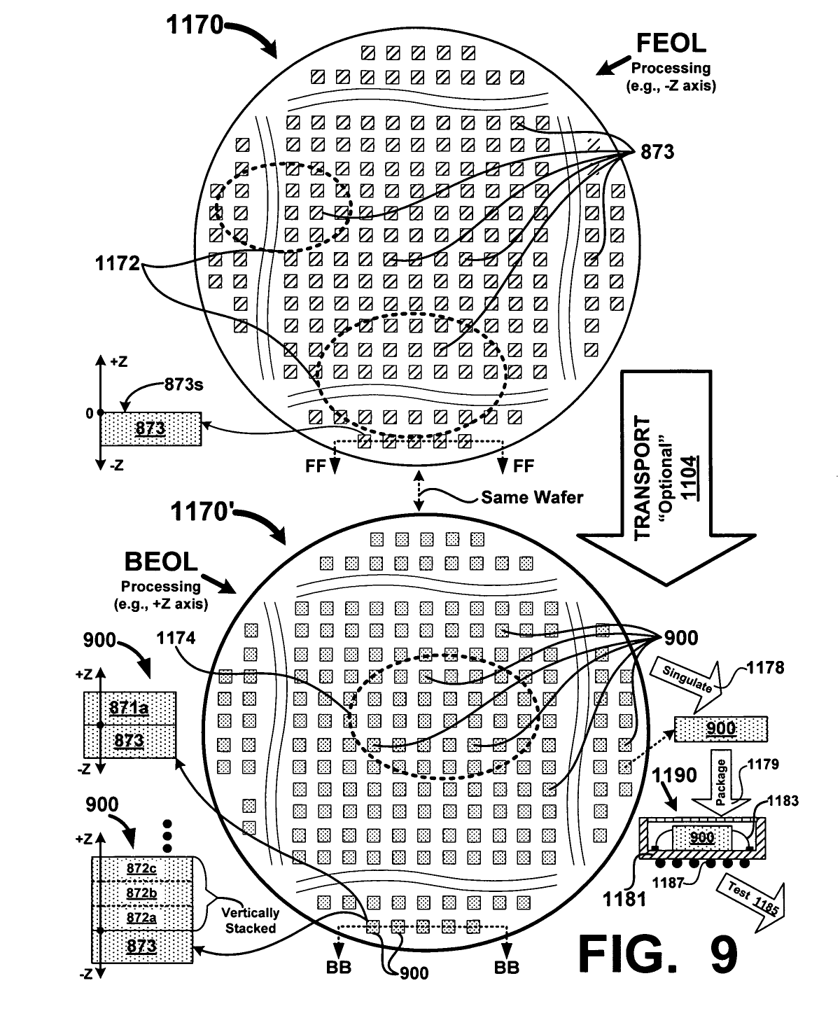

In FIG. 8A, a die 800 for an integrated circuit (IC) or an application specific integrated circuit (ASIC) includes a substrate 801 (e.g., a silicon wafer or silicon die) that includes a FEOL logic layer 803 having active circuitry 810-818 that is electrically coupled with conductive array lines 210 and 215 in a BEOL two-terminal cross-point memory array that is fabricated directly above the substrate 801 such that the die 800 is a unitary whole with the active circuitry monolithically fabricated FEOL in the logic layer 803 and one or more of the two-terminal cross-point memory arrays are fabricated BEOL in one or more memory planes (one is shown) that are in contact with one another and in contact with the substrate 801. Here, dielectric material 811 (e.g., SiO₂ or SiN_{X}) is operative to electrically isolate the conductive array lines 210 and 215 and memory elements 120 from one another and can also serve as the encapsulation material described above.

FIG. 8B depicts one example of multiple memory planes A, B, . . . to an nth plane that are in contact with one another and fabricated BEOL directly above the FEOL active circuitry 832-846 in logic plane 823 in substrate 821. Active circuitry 832-846 is electrically coupled with the conductive array lines (210a-210n and 215a-215n) in each memory plane and dielectric materials 825a-825n (e.g., SiO₂ or SiN_{X}) are operative to electrically isolate the conductive array lines (210a-210n and 215a-215n) and memory elements 120a-120n from one another and can also serve as the encapsulation material described above. In FIG. 8B, the cross-point arrays in each memory plane are completely electrically isolated from the arrays in adjacent memory planes so that memory elements 120 in each memory plane do not share conductive array lines with memory elements 120 in adjacent memory planes.

FIG. 8C depicts an alternate example of multiple memory planes A, B, C, D, . . . to an nth plane that are in contact with one another and fabricated BEOL directly above the FEOL active circuitry 852-866 in logic plane 853 in substrate 851. Dielectric material 855 (e.g., SiO₂ or SiN_{X}) is operative to electrically isolate the conductive array lines 210a-210c and 215a-215b and memory elements 120a-120d from one another and can also serve as the encapsulation material described above. In this example, the cross-point arrays include memory elements 120a-120d that share conductive array lines with memory elements in an adjacent memory plane.

FIG. 8D depicts two examples 870 of how an integrated circuit can be fabricated to include either a single layer of BEOL memory or multiple layers of BEOL memory. In a configuration 871, FEOL base layer 873 having circuitry 875 fabricated FEOL is fabricated first and then a single BEOL memory layer 871a is fabricated directly on top of an upper surface 873s of the FEOL base layer 873. The single memory layer 871a can include one or more two-terminal cross-point memory arrays 874. In another configuration 872, FEOL base layer 873 having circuitry 875 fabricated FEOL is fabricated first and then multiple BEOL memory layers 872a-872n are fabricated directly on top of an upper surface 873s of the FEOL base layer 873.

FIG. 9 depicts a fabrication flow for FEOL 1170 and BEOL 1170′ processing on the same silicon wafer. A top plan view depicts a single wafer (denoted as 1170 and 1170′) at two different stages of fabrication: FEOL processing on the wafer denoted as 1170 during the FEOL stage of processing where active circuitry 875 is formed; followed by BEOL processing on the same wafer denoted as 1170′ during the BEOL stage of processing where one or more layers of non-volatile memory are formed. Wafer 1170 includes a plurality of the base layer die 873 formed individually on wafer 1170 as part of the FEOL process. As part of the FEOL processing, the base layer die 873 may be tested 1172 to determine their electrical characteristics, functionality, performance grading, etc. After all FEOL processes have been completed, the wafer 1170 is optionally transported 1104 for subsequent BEOL processing (e.g., adding one or more layers of memory such as single layer 871a or multiple layers 872a-872n) directly on top of each base layer die 873. A base layer die 873 is depicted in cross-sectional view along a dashed line FF-FF where the substrate the die 873 is fabricated on (e.g., a silicon Si wafer) and its associated active circuitry 875 are positioned along the −Z axis. For example, the one or more layers of memory are grown directly on top of an upper surface 873s of each base layer die 873 as part of the subsequent BEOL processing.

During BEOL processing the wafer 1170 is denoted as wafer 1170′, which is the same wafer subjected to additional processing to fabricate the memory layer(s) directly on top of the base layer die 873. Base layer die 873 that failed testing may be identified either visually (e.g., by marking) or electronically (e.g., in a file, database, email, etc.) and communicated to the BEOL fabricator and/or fabrication facility. Similarly, performance graded base layer die 873 (e.g., graded as to frequency of operation) may identified and communicated to BEOL the fabricator and/or fabrication facility. In some applications the FEOL and BEOL processing can be done by the same fabricator or performed at the same fabrication facility. Accordingly, the transport 1104 may not be necessary and the wafer 1170 can continue to be processed as the wafer 1170′. The BEOL process forms the aforementioned memory layer(s) directly on top of the base layer die 720 to form a finished die 900 (see die 800, 820, and 850 in FIGS. 8A, 8B, and 8C) that includes the FEOL circuitry portion 873 along the −Z axis and the BEOL memory portion along the +Z axis. A cross-sectional view along a dashed line BB-BB depicts a memory device die 900 with a single layer of memory 871a grown (e.g., fabricated) directly on top of base die 873 along the +Z axis, and alternatively, another memory device die 900 with three vertically stacked layers of memory 872a, 872b, and 872c grown (e.g., fabricated) directly on top of base die 873 along the +Z. Finished die 900 on wafer 1170′ may be tested 1174 and good and/or bad die identified. Subsequently, the wafer 1170′ can be singulated 1178 to remove die 900 (e.g., die 900 are precision cut or sawed from wafer 1170′) to form individual memory device die 900. The singulated die 900 may subsequently be packaged 1179 to form integrated circuits 1190 for mounting to a PC board or the like, as a component in an electrical system (not shown). Here a package 1181 can include an interconnect structure 1187 (e.g., pins, solder balls, or solder bumps) and the die 900 mounted in the package 1181 and electrically coupled 1183 with the interconnect structure 1187 (e.g., using wire bonding). The integrated circuits 1190 (IC 1190 hereinafter) may undergo additional testing 1185 to ensure functionality and yield. One or more of the IC's 1190 can be used in a data storage system such as an embedded memory system (e.g., portable PC's, cell phones, PDA's, image capture devices, portable game players, MP3 players, video players, etc.), a RAID storage system in which the non-volatile memory in the one or more layers of memory in each IC 1190 is used to replace or supplant hard disc drives (HDD's) in the RAID system. Unlike conventional FLASH non-volatile memory, the IC's 1190 do not require an erase operation prior to a write operation so the latency associated with the erase operation is eliminated and the latency associated with FLASH OS and/or FLASH file system required for managing the erase operation is eliminated. Another application for the IC's 1190 is as a replacement for conventional FLASH-based non-volatile memory in solid state drives (SSD's). Here, one or more of the IC's 1190 can be mounted to a PC board along with other circuitry and placed in an appropriate enclosure to implement a SSD that can be used to replace a HDD. As mentioned above, the IC's 1190 do not require the erase before write operation and it associated latency and overhead. For both RAID and SSD applications, the vertically stacked memory arrays allow for increases in storage density without increasing die size because the memory arrays are fabricated above their associated active circuitry so extra memory capacity can be achieved by adding additional layers of memory above the FEOL base layer die 873.

In various embodiments, the CMO layer 101 can include one or more layers of a conductive oxide material, such as one or more layers of a conductive metal oxide-based (“CMO-based”) material, for example. In various embodiments, CMO layer 101 can include but is not limited to a perovskite material selected from one or more the following: PrCaMnO_{X} (PCMO), LaNiO_{X} (LNO), SrRuO_{X} (SRO), LaSrCrO_{X} (LSCrO), LaCaMnO_{X} (LCMO), LaSrCaMnO_{X} (LSCMO), LaSrMnO_{X} (LSMO), LaSrCoO_{X} (LSCoO), and LaSrFeO_{X} (LSFeO), where x is nominally 3 for perovskites or CMO layer 101 can be one or more layers of a conductive binary oxide structure comprised of a binary metal oxide having the form A_{X}O_{Y}, where A represents a metal and O represents oxygen. The conductive binary oxide material may be doped (e.g., with niobium—Nb, fluorine—F, and nitrogen—N) to obtain the desired conductive properties for a conductive binary oxide. In various embodiments, IMO layer 103 can include but is not limited to a material for implementing a tunnel barrier layer, the material being selected from one or more of the following: high-k dielectric materials, rare earth oxides, rare earth metal oxides, yttria-stabilized zirconium (YSZ), zirconia (ZrO_{X}), yttrium oxide (YO_{X}), erbium oxide (ErO_{X}), gadolinium oxide (GdO_{X}), lanthanum aluminum oxide (LaAlO_{X}), and hafnium oxide (HfO_{X}), aluminum oxide (Al₂O_{X}), and equivalent materials. The encapsulating material can include but is not limited to silicon oxide (SiO₂), silicon nitride (SiN_{X}), a silicate glass, and a doped silicate glass.

The ion implantation 321 can include silicon (Si) in addition to oxygen (O₂) and the implantation apparatus can include ion implantation equipment used in conventional CMOS device fabrication. The annealing 323 can occur at a temperature range from about 400° C. to about 500° C. The ambient 325 can include oxygen (O₂) or ozone (O₃). For example, the anneal 323 can be done at a temperature of 400° C. and the ambient 325 can be in an oxygen (O₂) ambient at a flow rate of approximately 55 liters/min of oxygen (O₂) for approximately one hour. Ion implantation energy for the implant 321 can range from about 10 keV to about 25 keV. Preferably in a range from about 10 keV to about 15 keV. Implant dose/cm² for the oxygen (O₂) ion species can range from about 1e16 to about 2e16. Implant dose/cm² for the silicon (Si) ion species can range from about 1e16 to about 4e16.

The various embodiments of the invention can be implemented in numerous ways, including as a system, a process, an apparatus, or a series of program instructions on a computer readable medium such as a computer readable storage medium or a computer network where the program instructions are sent over optical or electronic communication links. In general, the steps of disclosed processes can be performed in an arbitrary order, unless otherwise provided in the claims.

The foregoing description, for purposes of explanation, uses specific nomenclature to provide a thorough understanding of the invention. However, it will be apparent to one skilled in the art that specific details are not required in order to practice the invention. In fact, this description should not be read to limit any feature or aspect of the present invention to any embodiment; rather features and aspects of one embodiment can readily be interchanged with other embodiments. Notably, not every benefit described herein need be realized by each embodiment of the present invention; rather any specific embodiment can provide one or more of the advantages discussed above. In the claims, elements and/or operations do not imply any particular order of operation, unless explicitly stated in the claims. It is intended that the following claims and their equivalents define the scope of the invention.

1. A non-Flash re-writable non-volatile memory device, comprising:
a re-writeable non-volatile two-terminal memory element including
a first terminal,
a second terminal,
an oxygenated conductive metal oxide (CMO) layer including mobile oxygen ions, the oxygenated CMO layer comprises an oxygen ion implanted layer, and the oxygenated CMO layer is directly electrically coupled with the first terminal, and
an insulating metal oxide (IMO) layer in direct contact with the oxygenated CMO layer and directly electrically coupled with the second terminal, the IMO layer having a first thickness of approximately 50 Angstroms or less, and the IMO layer and the oxygenated CMO layer are electrically in series with each other and with the first and second terminals.

2. The memory device of claim 1, wherein the memory element is operative to store non-volatile data as a plurality of conductivity profiles that can be reversibly written by applying a write voltage across the first and second terminals, and the non-volatile data is non-destructively determined by applying a read voltage across the first and second terminals.

3. The memory device of claim 2, wherein an erase operation to the memory element is not required prior to applying the write voltage across the first and second terminals.

4. The memory device of claim 1, wherein the first thickness is selected to allow electron tunneling through the IMO layer when a voltage for a data operation is applied across the first and second terminals, and the IMO layer is permeable to at least a portion of the mobile oxygen ions when the write voltage is applied across the first and second terminals.

5. The memory device of claim 1, wherein the oxygenated CMO layer comprises an annealed layer.

6. The memory device of claim 5, wherein the annealed layer comprises an oxygen annealed layer.

7. The memory device of claim 1, wherein the memory element comprises an active and oxygenated region of the oxygenated CMO layer and portions of the oxygenated CMO layer that are adjacent to the active and oxygenated region comprise a silicon ion implanted region that is less electrically conductive than the active and oxygenated region of the memory element.

8. The memory device of claim 1, wherein the oxygenated CMO layer comprises a perovskite material.

9. The memory device of claim 1, wherein the oxygenated CMO layer comprises a plurality of layers of a perovskite material.

10. The memory device of claim 9, wherein at least one of the plurality of layers of the perovskite material comprises the oxygen ion implanted layer.

11. The memory device of claim 9, wherein one or more of the plurality of layers of the perovskite material are made from different perovskite materials.

12. The memory device of claim 9, wherein one or more of the plurality of layers of the perovskite material have substantially matching crystalline orientations.

13. The memory device of claim 1, wherein the oxygenated CMO layer comprises a binary oxide material.

14. The memory device of claim 1, wherein the oxygenated CMO layer comprises a plurality of layers of a binary oxide material.

15. The memory device of claim 14, wherein at least one of the plurality of layers of the binary oxide material comprises the oxygen ion implanted layer.

16. The memory device of claim 14, wherein one or more of the plurality of layers of the binary oxide material are made from different perovskite materials.

17. The memory device of claim 14, wherein one or more of the plurality of layers of the binary oxide material have substantially matching crystalline orientations.

18. The memory device of claim 1 and further comprising: at least one encapsulation material configured to contain the mobile oxygen ions in the oxygenated CMO layer, the IMO layer, or both.

19. The memory device of claim 18, wherein the at least one encapsulation material comprises a dielectric material.

20. The memory device of claim 18, wherein the at least one encapsulation material comprises an electrically conductive material that is a component of the first terminal, the second terminal, or both.

21. The memory device of claim 18, wherein the at least one encapsulation material is in direct contact with at least a portion of the oxygenated CMO layer.

22. The memory device of claim 1, wherein a concentration of implanted oxygen ions varies in at least a portion of the oxygen ion implanted layer.

23. The memory device of claim 1, wherein the memory element comprises a back-end-of-the-line (BEOL) memory element and the first and second terminals are in electrical communication with front-end-of-the-line (FEOL) active circuitry fabricated on a semiconductor substrate and configured to perform data operations on the BEOL memory element.
